(19) United States
(12) Patent Application Publication
(10) Pub. No.: US 2009/0178829 A1
(43) Pub. Date: Jul. 16, 2009

(54) ANTI-BREAKAGE STRUCTURE FOR TRANSMITTING END FORMED ON FLEXIBLE PRINTED CIRCUITBOARD

(75) Inventors: Tsui-Chuan WANG, Taichung County (TW); Chin-Mei HUANG, Taichung City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: WINTEX CORPORATION, Taichung (TW)

(21) Appl. No.: 12/352,038

(22) Filed: Jan. 12, 2009

(30) Foreign Application Priority Data
Jan. 15, 2008 (TW) 097200886

(51) Int. Cl. H05K 1/00

(52) U.S. Cl. 174/254

(57) ABSTRACT

An anti-breakage structure for a transmitting end of flexible printed circuitboard (FPC) is disclosed, which comprises at least a via hole, being formed on the FPC at a position corresponding to each pin of the transmitting end while enabling the at least one via hole formed on any two neighboring pins to be arranged in a staggered manner without being align on the same line. As the via holes formed on any two neighboring pins of the FPC's transmitting end are not aligned with each other but are scattered so that the area where stress is likely to concentrate is increased when the FPC is subjected to an external force, stresses can be distributed evenly through the whole transmitting end of the FPC without forming any specific stress concentration area.

### CROSS-REFERENCE TO RELATED APPLICATIONS

This non-provisional application claims priority under 35 U.S.C. §119(a) on Patent Application No. 097200886 filed in Taiwan on Jan. 15, 2008, the entire contents of which are hereby incorporated by reference.

### FIELD OF THE INVENTION

The present invention relates to an anti-breakage structure for transmitting end formed on flexible printed circuitboard (FPC), and more particularly, to an anti-breakage structure for a FPC, substantially being staggered-arranged via holes formed on the pins of a transmitting end of the FPC in a manner that they are not aligned on the same line.

### BACKGROUND OF THE INVENTION

With rapid advance of technology and the improvement of our living quality, the designs for all kinds of consumer electronic products, including hand-held computers, palm-sized game consoles and smart phones, are becoming more and more diversified while their lifespan are shorten as well. Among all those innovated new designs, the so-called clam-shell or foldable design is most welcomed by consumers and thus becoming the main stream in the market. Moreover, almost all of those foldable electronic products adopt the design of configuring a flexible printed circuitboard (FPC) at their bending areas to be used for transmitting electric signals. As the FPC is flexible, light-weighted and thin, it is especially suitable for those consumer electronic products of moveable structures that are designed to be thinner, lighter and smaller.

Generally, the conventional FPC is used as an interface for transmitting electric signals between two electronic devices. For instance, it is used for communicating signals between a monitor and mother board in a notebook computer, or for connecting the two in a cellular phone. Moreover, for increasing soldering integrity, it is common to form via holes in alignment on the pins of a transmitting end of the FPC. That is, when connecting a FPC with aforesaid via holes to an electronic device by soldering, solder can be fed into the via holes and thus strengthened the combination between the pins and the electronic devices. However, also because the via holes are arranged in alignment on the transmitting end of the FPC, the area where stress is likely to concentrate is minimum as stress will distributed around each via hole and thus highly concentrated about the area of the via holes, it is more than likely to cause circuits in the FPC to break or tear when the FPC is handle carelessly during transportation or assembly, and that is true even when the FPC is picked up by an operator during assembly by the corner near its pins.

### SUMMARY OF THE INVENTION

In view of the disadvantages of prior art, the object of the present invention is to provide an anti-breakage structure for a transmitting end formed on a flexible printed circuitboard (FPC), capable of effectively preventing the corner of the FPC near the pins of the transmitting end from breaking.

To achieve the above object, the present invention provides an anti-breakage structure for a transmitting end of flexible printed circuitboard (FPC), comprising: at least a via hole, being formed on the FPC at a position corresponding to each pin of the transmitting end while enabling the at least one via hole formed on any two neighboring pins to be arranged in a staggered manner without being align on the same line.

As the via holes formed on any two neighboring pins of the FPC's transmitting end are not aligned with each other but are scattered so that the area where stress is likely to concentrate is increased, stresses can be distributed evenly through the whole transmitting end of the FPC without forming any specific stress concentration area when the FPC is subjected to an external force.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 shows a conventional anti-breakage structure formed on the transmitting end of a flexible printed circuitboard.

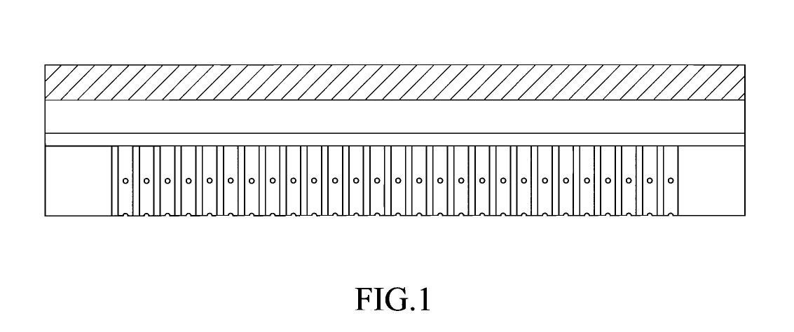

FIG. 2 is a schematic diagram showing a single-hole anti-breakage structure formed on the transmitting end of a flexible printed circuitboard according to a first embodiment of the invention.

FIG. 3 is a schematic diagram showing a single-hole anti-breakage structure formed on the transmitting end of a flexible printed circuitboard according to a second embodiment of the invention.

FIG. 4 is a schematic diagram showing a single-hole anti-breakage structure formed on the transmitting end of a flexible printed circuitboard according to a third embodiment of the invention.

FIG. 5 is a schematic diagram showing a multiple-hole anti-breakage structure formed on the transmitting end of a flexible printed circuitboard according to a first embodiment of the invention.

FIG. 6 is a schematic diagram showing a multiple-hole anti-breakage structure formed on the transmitting end of a flexible printed circuitboard according to a second embodiment of the invention.

FIG. 7 is a schematic diagram showing a multiple-hole anti-breakage structure formed on the transmitting end of a flexible printed circuitboard according to a third embodiment of the invention.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

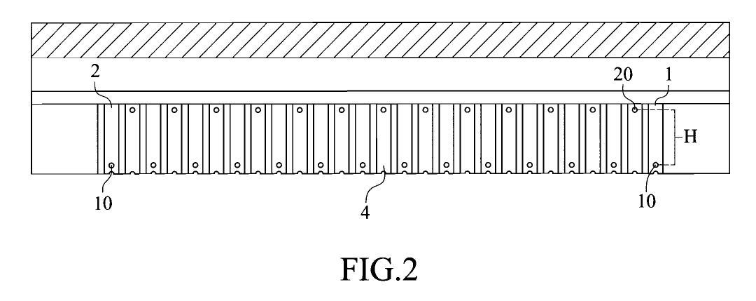

Please refer to FIG. 2, which is a schematic diagram showing a single-hole anti-breakage structure formed on the transmitting end of a flexible printed circuitboard according to a first embodiment of the invention. As shown in FIG. 2, there are via holes formed on the transmitting end of a FPC in a staggered manner. That is, starting from one of the two outermost pins 1, 2 in the transmitting end to the center thereof, the via hole 10 formed on one of the two outermost pins 1, 2 in the transmitting end is located at the bottom portion thereof while enabling the via hole 20 formed on another pin neighbor to the outermost pin 1, 2 to be located at a top portion of the aforesaid neighbor pin, and then enabling the via hole formed on the pin to the center and next to the aforesaid neighbor pin to be located at its bottom portion, and sequentially up-and-down thereafter until a stop point is reached. It is noted that the via hole 20 located at the top portion is spaced from the via hole 10 located at the bottom portion by a distance H, in that the distance H can be determined according to actual requirement and thus is not restricted by the present embodiment.

In this embodiment, the pin 4 located at the center of the transmitting end is used as the stop point, by that the aforesaid staggered disposition of via holes from one of the two outermost pins 1, 2 is stopped as soon as the stop point is reached and then another staggered disposition of via holes is started from another outermost pin toward the center pin 4. On the other hand, the staggered disposition of via holes can be started from the two outermost pins 1, 2 at the same time and continues toward the center pin 4 where they are stopped. Thereby, the via holes are symmetrically disposed with respect to the center pin 4.

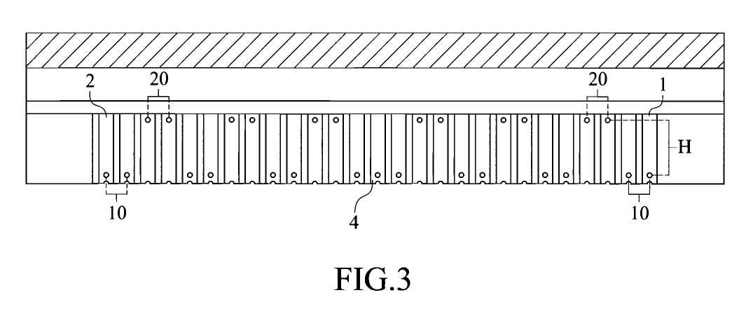

Please refer to FIG. 3, which is a schematic diagram showing a single-hole anti-breakage structure formed on the transmitting end of a flexible printed circuitboard according to a second embodiment of the invention. In this embodiment, starting from the outermost part 1 of the transmitting end to the center, the formation of the via holes on the pins is arranged as following: the via holes on the two neighboring pins located at an outermost part 1, 2 of the transmitting end are formed at their bottom portions 10, and then the two via holes on two neighboring pins to the center and neighbor to the aforesaid two outmost pins are formed at their top portions 20, and sequentially up-and-down thereafter until a stop point specified about the center of the transmitting end is reached; and the aforesaid via hole disposition is also true from the two neighboring pins located at another outermost end 2. It is noted that the via hole 20 located at the top portion is spaced from the via hole 10 located at the bottom portion by a distance H.

Similarly, the pin 4 located at the center of the transmitting end is used as the stop point, by that the aforesaid staggered disposition of via holes starting from one of the two outermost part 1, 2 is stopped as soon as the stop point is reached and then another staggered disposition of via holes is started from another outermost part toward the center pin 4. On the other hand, the staggered disposition of via holes can be started from the two outermost parts 1, 2 at the same time and continues toward the center pin 4 where they are stopped. Thereby, the via holes are symmetrically disposed with respect to the center pin 4.

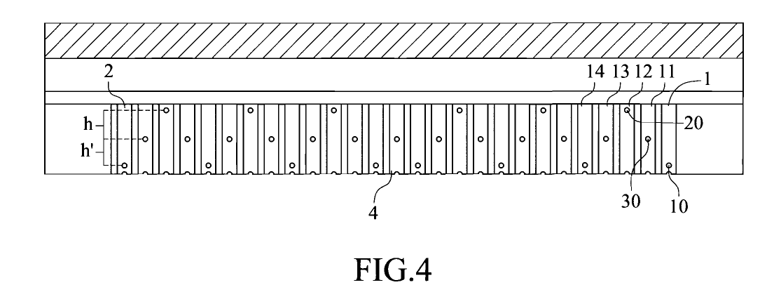

Please refer to FIG. 4, which is a schematic diagram showing a single-hole anti-breakage structure formed on the transmitting end of a flexible printed circuitboard according to a third embodiment of the invention. In the single-hole anti-breakage structure 3 shown in FIG. 4, the formation of the via holes on the pins is arranged as following: starting from two outermost pins 1, 2 to the center of the transmitting end, the formation of the via holes on the pins is arranged as a wave that undulates starting by locating one via hole 10 at a bottom portion of the outermost pin 1, then locating another via hole 30 at a middle portion at the pin 11 next to the outermost pin 1, and then locating another via hole 20 at a top portion of the pin 12 to the center and next to the pin 11, and then locating another via hole 30 at a middle portion at the pin 13 to the center and next to the pin 12, and locating another via hole 10 at a bottom portion of the pin 15 the center and next to the pin 14, and sequentially undulating thereafter until a stop point specified about the center of the transmitting end is reached. It is noted that the via hole 20 located at the top portion is spaced from the via hole 30 located at the middle portion by a distance h, and similarly, the via hole 30 located at the middle portion is spaced from the via hole 10 located at the bottom portion by another distance h′. The two distances h and h′ can varied through out between pins the whole transmitting end. In this embodiment, the two distances h and h′ remain unchanged between pins through out the whole transmitting end, however, they can be determined according to actual requirement and are not restricted thereby.

Similarly, the pin 4 located at the center of the transmitting end is used as the stop point, by that the aforesaid undulating waveform disposition of via holes starting from one of the two outermost pin 1, 2 is stopped as soon as the stop point is reached and then another undulating waveform disposition of via holes is started from another outermost pin toward the center pin 4. On the other hand, the undulating waveform disposition of via holes can be started from the two outermost pins 1, 2 at the same time and continues toward the center pin 4 where they are stopped. Thereby, the via holes are symmetrically disposed with respect to the center pin 4.

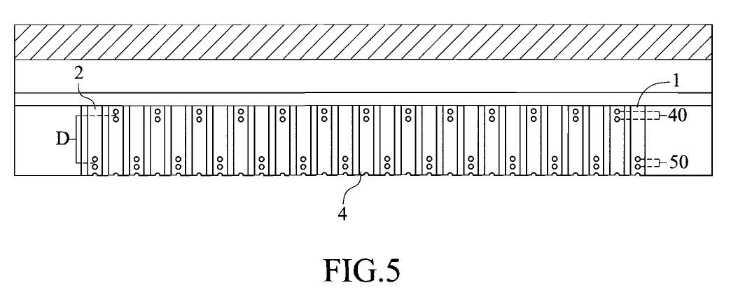

Please refer to FIG. 5, which is a schematic diagram showing a multiple-hole anti-breakage structure formed on the transmitting end of a flexible printed circuitboard according to a first embodiment of the invention. In the embodiment shown in FIG. 5, there are via holes formed on the transmitting end of a FPC in a staggered manner while enabling each pin in the transmitting end to be formed with multiple via holes and the distances between the via holes on the same pin are equal to each other. That is, starting from one of the two outermost pins 1, 2 in the transmitting end to the center thereof, the set of via holes 50 formed on one of the two outermost pins 1, 2 in the transmitting end is located at the bottom portion thereof while enabling the set of via holes 40 formed on another pin neighbor to the outermost pin 1, 2 to be located at a top portion of the aforesaid neighbor pin, and sequentially up-and-down thereafter until a stop point is reached. It is noted that the set of via holes 40 located at the top portion is spaced from the set of via holes 50 located at the bottom portion by a distance D, in that the distance D is measured between the middle of the set of via holes 40 and the set of via holes 50 and can be determined according to actual requirement which is not restricted by the present embodiment.

Similarly, the pin 4 located at the center of the transmitting end is used as the stop point, by that the aforesaid staggered disposition of via hole sets starting from one of the two outermost pin 1, 2 is stopped as soon as the stop point is reached and then another staggered disposition of via hole sets is started from another outermost pin toward the center pin 4. On the other hand, the staggered disposition of via hole sets can be started from the two outermost pins 1, 2 at the same time and continues toward the center pin 4 where they are stopped. Thereby, the via hole sets are symmetrically disposed with respect to the center pin 4.

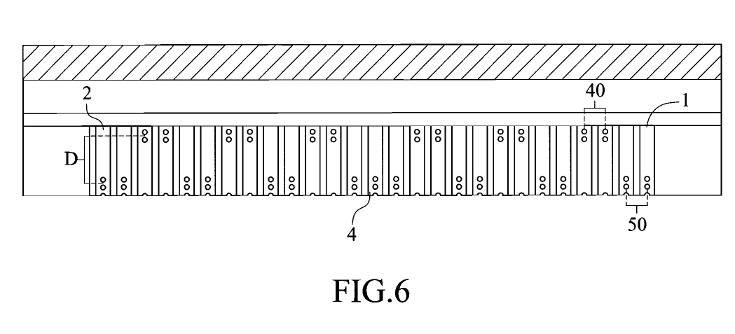

Please refer to FIG. 6, which is a schematic diagram showing a multiple-hole anti-breakage structure formed on the transmitting end of a flexible printed circuitboard according to a second embodiment of the invention. In this embodiment, starting from the outermost part 1 of the transmitting end to the center, the formation of the via hole sets on the pins is arranged as following: while enabling the distances between via holes on the same pin to be the equal, the via hole sets 50 on the two neighboring pins located at an outermost part 1, 2 of the transmitting end are formed at their bottom portions, and then the two via hole sets 40 on two neighboring pins to the center and neighbor to the aforesaid two outmost pins are formed at their top portions, and sequentially up-and-down thereafter until a stop point specified about the center of the transmitting end is reached; and the aforesaid via hole sets disposition is also true from the two neighboring pins located at another outermost end 2. It is noted that the set of via holes 40 located at the top portion is spaced from the set of via holes 50 located at the bottom portion by a distance D, in that the distance D is measured between the middle of the set of via holes 40 and the set of via holes 50.

Similarly, the pin 4 located at the center of the transmitting end is used as the stop point, by that the aforesaid staggered disposition of via hole sets starting from two pins located at one of the two outermost part 1, 2 is stopped as soon as the stop point is reached and then another staggered disposition of via hole sets is started from the two pins located at another outermost part toward the center pin 4.

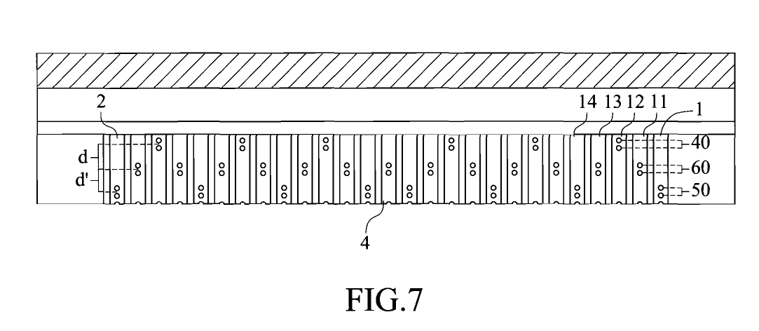

Please refer to FIG. 7, which is a schematic diagram showing a multiple-hole anti-breakage structure formed on the transmitting end of a flexible printed circuitboard according to a third embodiment of the invention. In the multiple-hole anti-breakage structure shown in FIG. 7, the formation of the via hole sets on the pins is arranged as following: while enabling the distances between the via holes on the same pin to be equal and starting from two outermost pins 1, 2 to the center of the transmitting end, the formation of the via hole sets on the pins is arranged as a wave that undulates starting by locating one via hole set 50 at a bottom portion of the outermost pin 1, then locating another via hole set 60 at a middle portion at the pin 11 next to the outermost pin 1, and then locating further another via hole set 40 at a top portion of the pin 12 to the center and next to the pin 1 1, and then locating yet another via hole set 60 at a middle portion at the pin 13 to the center and next to the pin 12, and locating another via hole set 50 at a bottom portion of the pin 15 the center and next to the pin 14, and sequentially undulating thereafter until a stop point specified about the center of the transmitting end is reached. It is noted that the via hole set 40 located at the top portion is spaced from the via hole 60 located at the middle portion by a distance d, and similarly, the via hole 60 located at the middle portion is spaced from the via hole 50 located at the bottom portion by another distance d′. The two distances d and d′ are measured between the middles of the corresponding via hole sets and can be determined according to actual requirement and are not restricted thereby.

Similarly, the pin 4 located at the center of the transmitting end is used as the stop point, by that the aforesaid undulating waveform disposition of via hole sets starting from one of the two outermost pin 1, 2 is stopped as soon as the stop point is reached and then another undulating waveform disposition of via hole sets is started from another outermost pin toward the center pin 4. On the other hand, the undulating waveform disposition of via hole sets can be started from the two outermost pins 1, 2 at the same time and continue toward the center pin 4 where they are stopped. Thereby, the via hole sets are symmetrically disposed with respect to the center pin 4.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. An anti-breakage structure for a transmitting end of a flexible printed circuitboard (FPC), comprising:
at least a via hole, being formed on the FPC at a position corresponding to each pin of the transmitting end while enabling the at least one via hole formed on any two neighboring pins to be arranged in a staggered manner without being align on the same line.

2. The anti-breakage structure of claim 1, wherein, the at least one via hole formed respectively on any two neighboring pins are arranged in a staggered manner as following: starting from an outermost pin in the transmitting end to the center thereof, the at least one via hole formed on the outermost pin is located at a bottom position of the outermost pin while enabling the at least one via hole formed on another pin neighbor to the outermost pin to be located at a top portion of the aforesaid neighbor pin, and then enabling the at least one via hole formed on the pin to the center and next to the aforesaid neighbor pin to be located at its bottom portion, and sequentially up-and-down thereafter until a stop point specified about the center of the transmitting end is reached.

3. The anti-breakage structure of claim 1, wherein the formation of the via holes on the pins is arranged as following: starting from the outermost of the transmitting end to the center, the at least one via hole on the two neighboring pins located at the outermost of the transmitting end are formed at their bottom portions, and then the at least one via hole on two neighboring pins to the center and neighbor to the aforesaid two outmost pins are formed at their top portions, and sequentially up-and-down thereafter until a stop point specified about the center of the transmitting end is reached.

4. The anti-breakage structure of claim 1, wherein, starting from two outermost pins to the center of the transmitting end, the formation of the via holes on the pins is arranged as a wave that undulates starting from the two via holes located respectively at bottom portions of the two outermost pins toward the center of the transmitting end.

5. The anti-breakage structure of claim 1, wherein each pin in the transmitting end is formed with a plurality of via holes.

6. The anti-breakage structure of claim 5, wherein the interval between any two via holes in the plural via holes is a constant.
